(19) United States
(12) Patent Application Publication
(10) Pub. No.: US 2024/0105763 A1
(43) Pub. Date: Mar. 28, 2024

(54) METAL-INSULATOR-METAL CAPACITOR DEVICE WITH INTEGRATED WIRE BONDING SURFACE

(71) Applicant: Wolfspeed, Inc., Durham, NC (US)

(72) Inventors: Jeremy Fisher, Raleigh, NC (US); Marvin Marbell, Cary, NC (US); Dan Namishia, Wake Forest, NC (US); Dan Etter, Durham, NC (US)

(21) Appl. No.: 17/952,267

(22) Filed: Sep. 25, 2022

(51) Int. Cl. H01L 49/02; H01L 23/522; H01L 23/66; H01L 29/20; H01L 29/778

(52) U.S. Cl. CPC H01L 28/40; H01L 23/5223; H01L 23/66; H01L 29/2003; H01L 29/7783; H01L 29/7787

(57) ABSTRACT

A device according to some embodiments includes a metal-insulator-metal (MIM) capacitor including a substrate, an upper metal plate, and a lower metal surface attached to a first surface of the substrate. The upper metal plate of the MIM capacitor is configured to serve as a wire bonding surface. Other embodiments include an RF transistor package and a device including a MIM capacitor that includes at least one via.

### FIELD

The disclosure relates to metal-insulator-metal (MIM) capacitor devices with an upper metal plate configured to serve as an integrated wire bonding surface.

### BACKGROUND

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H—SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 10¹³ carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

A GaN-based HEMT can be formed on a silicon carbide substrate. A GaN channel layer can be on the substrate, and an AlGaN barrier layer can be on the channel layer. A 2DEG can arise in the channel layer adjacent the barrier layer. A source contact and a drain contact can be formed on the channel layer. The conductivity of the 2DEG can be modulated by applying a voltage to a gate that can be formed on the barrier layer between the source contact and the drain contact.

Packaged transistors have been used that include a transistor (e.g., a HEMT) in a metal-based package along with matching components of an input matching circuit and/or an output matching circuit between the package leads and transistor gate and drain pads. The matching components of the input matching circuit and/or an output matching circuit of the package typically are used to match an impedance (e.g., 50 ohms) for a particular frequency (e.g., 3.1 GHz) or a particular frequency range (e.g., 3.1-3.5 GHz).

Packaged transistors may be implemented as monolithic microwave integrated circuits (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

Packaged transistors also may be implemented with integrated passive device (IPD) components. Typically, the IPD components are mounted on printed circuit board (PCB) based substrates, silicon (Si) based substrates, and/or the like.

FIG. 1 is a plan view of a conventional submount/package 100 that includes a component/circuit 102 (e.g., a monolithic microwave integrated circuit (MMIC), a radio frequency (RF) transistor amplifier implementing RF transistors with IPD components, etc.). Package 100 includes a MIM capacitor 104 that is connected to a separate bond pad 106. The separate bond pad 106 is connected to a first end of one or more wire bonds 108. As shown in FIG. 1, component/circuit 102 is connected to a second end of the one or more wire bonds 108. The submount or package 100 may include a protective housing that surrounds and protects the component/circuit 102, the MIM capacitor 104, bond pad 106, and wire bonds 108. The protective housing may be formed of, for example, a ceramic or plastic material.

### SUMMARY

A device according to some embodiments includes a MIM capacitor including a substrate, an upper metal plate, and a lower metal surface attached to a first surface of the substrate. The upper metal plate of the MIM capacitor is configured to serve as a wire bonding surface.

The upper metal plate of the MIM capacitor configured to serve as a wire bonding surface may be configured to attach with at least one wire bond to a component or a circuit on a separate surface in a package.

The separate surface in the package may include one of a substrate, a die, a submount, and a carrier.

The component or the circuit may include a gallium nitride (GaN) based HEMT.

The component or the circuit may include an IPD including one or more passive electronic components.

The IPD may include silicon carbide (SiC) components.

The MIM capacitor may include a shunt capacitor.

The component or the circuit may include a MMIC.

The MMIC may include a Group III nitride-based material on SiC.

The MIM capacitor may include a series blocking capacitor or a shunt direct current (DC) bypass capacitor.

The MIM capacitor may have a capacitance in a range of about 1 to 1000 pF.

The device may include a GaN based HEMT.

The device may be configured to operate at frequencies greater than 1 GHz.

The device may be configured to operate at frequencies greater than 2.5 GHz.

The device may be configured to operate at frequencies greater than 3.1 GHz.

The device may be configured to operate at frequencies greater than 5 GHz.

An RF transistor package according to some embodiments includes a submount and a transistor die mounted on the submount. The transistor die includes a top surface and a bottom surface. The bottom surface is mounted to the submount. The RF transistor package further includes a MIM capacitor mounted to the submount. The MIM capacitor includes a substrate, a lower metal surface attached to a first surface of the substrate, and an upper metal plate configured to serve as a wire bonding surface. The RF transistor package further includes a wire bond including a first end connected to the wire bonding surface of the MIM capacitor and a second end connected to the top surface of the transistor die in the RF transistor package.

The transistor die may include one or a plurality of GaN based HEMTs.

The MIM capacitor may include a shunt capacitor.

The MIM capacitor may include a series blocking capacitor or a shunt DC bypass capacitor.

The substrate of the MIM capacitor may include SiC.

The MIM capacitor may have a capacitance in a range of about 1 to 1000 pF.

The substrate of the MIM capacitor may include a substrate that includes SiC.

The RF transistor package may be configured to operate at frequencies greater than 1 GHz.

The RF transistor package may be configured to operate at frequencies greater than 2.5 GHz.

The RF transistor package may be configured to operate at frequencies greater than 3.1 GHz.

The RF transistor package may be configured to operate at frequencies greater than 5 GHz.

A device according to some embodiments includes a MIM capacitor including (i) a substrate comprising a first surface and a second surface, (ii) an upper metal plate configured for wire bonding, (iii) a lower metal surface attached to the first surface of the substrate, (iv) a dielectric material disposed between the upper metal plate and the lower metal surface, and (v) at least one via disposed through the substrate.

The at least one via disposed through the substrate may be surrounded by material of the substrate, the upper metal plate configured for wire bonding may be disposed on the via and the surrounding material of the substrate, and the upper metal plate configured for wire bonding may be configured for at least one wire bond attachment to the upper metal plate disposed on a portion of the surrounding material of the substrate.

The upper metal plate configured for wire bonding may be configured to attach with at least one wire bond to a component or a circuit on a separate surface in a package.

The separate surface may include one of a substrate, a die, a submount, and a carrier.

The component or the circuit may include an IPD including one or more passive electronic components.

The IPD may include SiC components.

The MIM capacitor may include a shunt capacitor.

The component or the circuit may include a MMIC.

The MMIC may include a Group III nitride-based material on SiC.

The MIM capacitor may include a series blocking capacitor or a shunt DC bypass capacitor.

The substrate of the MIM capacitor may include SiC.

The MIM capacitor may have a capacitance in a range of about 1 to 1000 pF.

The device may include a GaN based HEMT.

The device may be configured to operate at frequencies greater than 1 GHz. The device may be configured to operate at frequencies greater than 2.5 GHz.

The device may be configured to operate at frequencies greater than 3.1 GHz.

The device may be configured to operate at frequencies greater than 5 GHz.

Additional features, advantages, and aspects of the disclosure may be set forth or apparent from consideration of the following detailed description, drawings, and claims. Moreover, it is to be understood that both the foregoing summary of the disclosure and the following detailed description includes examples and intended to provide further explanation without limiting the scope of the disclosure as claimed.

### BRIEF DESCRIPTION OF THE DRAWINGS

The accompanying drawings, which are included to provide a further understanding of the disclosure, are incorporated in, and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a schematic illustration of a conventional submount or package.

FIG. 2 is a schematic layout of a conventional MIM capacitor and separate bond pad.

FIG. 3 is a schematic diagram illustrating a MIM capacitor device and submount/package according to some embodiments of the present disclosure.

FIG. 4 is a schematic layout of a MIM capacitor device according to some embodiments of the present disclosure.

FIG. 5 is a schematic block diagram of a MIM capacitor device according to some embodiments of the present disclosure.

FIGS. 6A-6C are schematic block diagrams of multi-amplifier circuits in which RF transistor amplifiers incorporating transistor devices connected to a MIM capacitor device according to embodiments may be used.

FIG. 7 is a schematic illustration of a plan view of a MMIC amplifier in which a HEMT transistor connected to a MIM capacitor device according to embodiments may be used.

FIGS. 8A and 8B illustrate packaged MMICs according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Integrated circuits (ICs), such as MMICs and/or IPDs, are conventionally enclosed in packages that enable electrical interconnection between semiconductor chips and other electrical components, such as a printed circuit board, submount, SiC based substrates, silicon (Si) based substrates, and/or the like. In some cases, such as GaN-on-SiC MMICs and/or SiC IPD components, the MMIC or IPD is electrically connected to external, off chip circuitry. The external, off chip circuitry can be a MIM capacitor. The MIM capacitor can include a top metal layer, a bottom metal layer, and a dielectric material between the top and bottom metal layers.

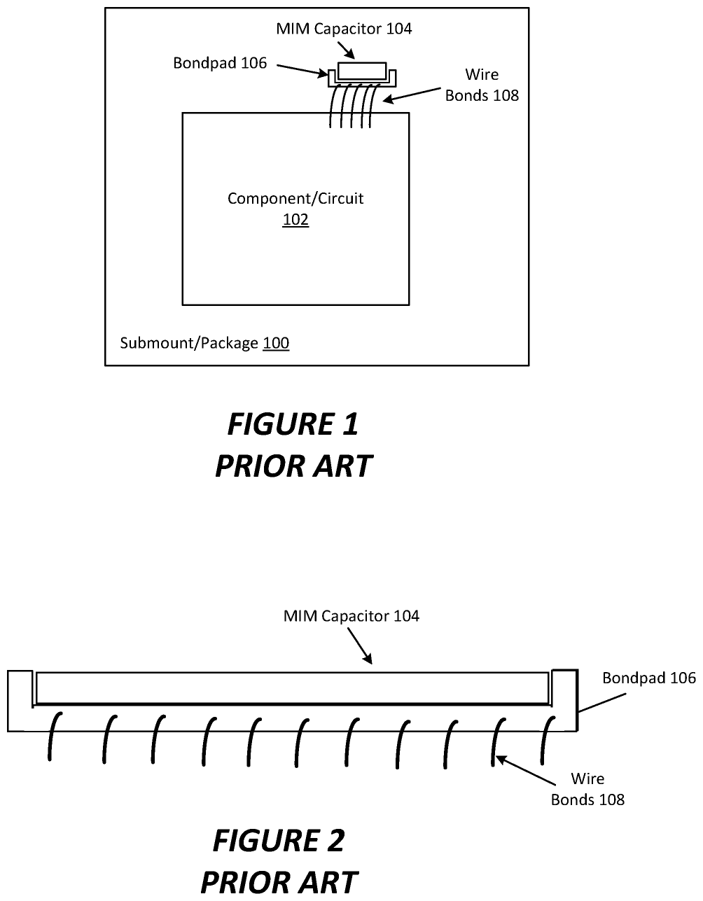

Connection to the MIM capacitor, however, can include a separate bond pad proximate to the MIM capacitor. FIG. 2 is a schematic layout of a conventional MIM capacitor 104 with separate bond pad 106 illustrated in FIG. 1. As shown in FIGS. 1 and 2, connection of external MIM capacitor 104 to a component/circuit 102 conventionally is achieved via separate bond pad 106 and wire bonds 108. However, this results in an increased amount of space used for the separate bond pad 106 and, as a consequence, may also result in increased manufacturing complexity, time, manufacturing costs, and/or the like.

Direct wire bonding to a MIM capacitor, however, may result in decreased reliability of the MIM capacitor. For example, direct wire bonding to a MIM capacitor may result in deformation of a top metal layer of the MIM capacitor and/or pinching of the dielectric material between the top and bottom metal layers of the MIM capacitor as a consequence of the deformation.

Various embodiments described herein can reduce the cost, size, and/or complexity of MIM capacitor devices by eliminating the need for a separate bond pad for an electrical connection between the MIM capacitor and a separate circuit/component (e.g., such as a separate GaN-on-SiC MMIC or a SiC IPD component). Moreover, acceptable reliability of a MIM capacitor device having a direct wire bond attachment may be achieved. For example, MIM capacitors that do not include a separate bond pad may include one or more vias in the structure of the MIM capacitor. Direct wire bonding to the MIM capacitor may be applied to a top metal plate of the MIM capacitor in between vias (in other words, not on the vias) in a manner that minimizes/does not result in metal deformation/pinching of the dielectric material. Other techniques may also be used to provide MIM capacitor devices with a separate bond pad, according to various embodiments described herein.

Some embodiments herein are described generally with reference to packaged transistors, MMIC RF power amplifier transistors, and/or an RF product that implements SiC IPD components for ease of understanding the description herein. However, it will be understood by those having skill in the art that other embodiments of the present disclosure may be based on a variety of different combinations of other types of semiconductor devices, such as MOSFETs, DMOS transistors, GaAs CMOS, and/or laterally diffused MOS (LDMOS) transistors.

Some embodiments provide a MIM capacitor including a substrate, an upper metal plate, and a lower metal surface attached to a first surface of the substrate. The upper metal plate of the MIM capacitor is configured to serve as an integrated wire bonding surface. The wire bonding surface is integrated with the MIM capacitor as the wire bonding surface also acts as a capacitor plate for the MIM capacitor. The upper metal plate of the MIM capacitor configured to serve as an integrated wire bonding surface can be configured to attach with at least one wire bond to a component or a circuit on a separate surface in a package.

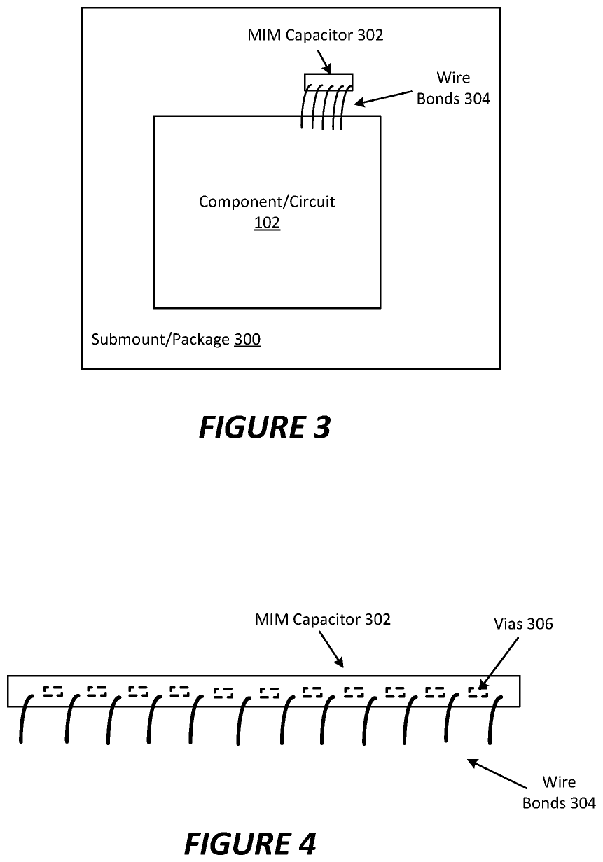

An example arrangement according to some embodiments is illustrated schematically for a submount/package including a MIM capacitor device in FIG. 3. As shown in FIG. 3, a submount/package 300 includes a component/circuit 102 formed on the submount/package 300. MIM capacitor 302 is also formed on submount/package 300, separate from component/circuit 102. MIM capacitor 302 is connected to a first end of one or more wire bonds 304. Component/circuit 102 is connected to a second end of the one or more wire bonds 304.

Wire bonds 304 may include wires. The wires can include aluminum, copper, silver, and/or gold, for example. Wire bond attachment techniques may include ball bonding, wedge bonding and/or compliant bonding. In ball bonding and wedge bonding, the wire is attached at both ends using some combination of heat, pressure, and ultrasonic energy to make a weld. In compliant bonding, heat and pressure is transmitted through a compliant or indentable aluminum tape.

FIG. 4 is a schematic layout of a MIM capacitor device 302 according to some embodiments of the present disclosure. As shown in FIG. 4, MIM capacitor 302 is connected to a first end of one or more wire bonds 304, e.g., by bonding directly to a top plate of MIM capacitor 304. Based on an upper metal plate of the MIM capacitor 302 being configured to serve as a wire bonding surface, a separate bond pad near MIM capacitor 302 is not needed, which may result in reducing fabrication time, complexity, cost, and/or the amount of space needed for MIM capacitor 302 on submount/package 300. As discussed further herein, MIM capacitor device 302 can further include one or more vias 306, shown with dashed lines in FIG. 4.

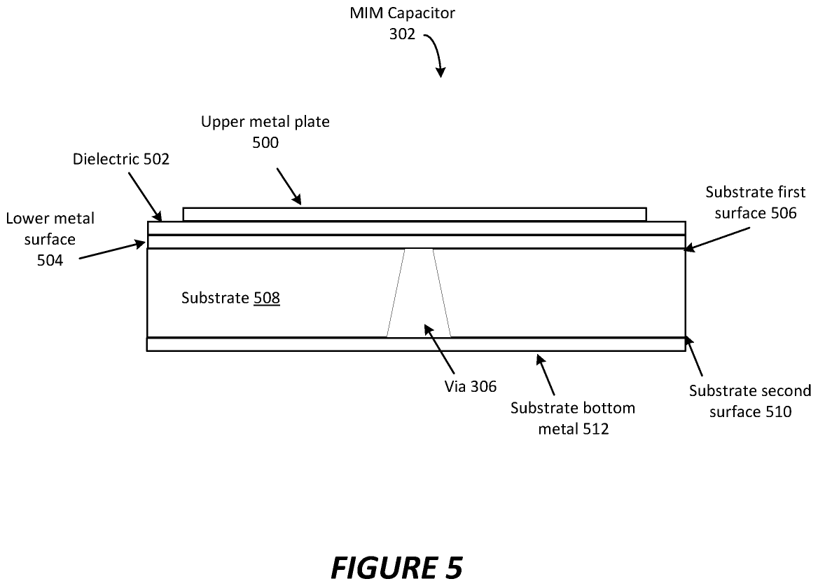

FIG. 5 is a cross-sectional view of a MIM capacitor device according to various embodiments described herein. As shown in FIG. 5, the MIM capacitor device 302 includes upper metal plate 500, dielectric 502, lower metal surface 504, substrate 508, and substrate bottom metal 512.

The substrate 508 (also referred to herein as a device substrate or a RF transistor substrate) includes a semiconductor material. In some embodiments, the substrate 508 may include insulating substrates, wideband substrates, gallium arsenide (GaAs) substrates, or the like. In an example embodiment, the substrate includes SiC.

As shown in FIG. 5, a MIM capacitor structure is formed over substrate 508. The MIM capacitor structure includes upper metal plate 500, lower metal surface 504, and a dielectric layer 502 between the upper metal plate 500 and the lower metal surface 504.

The upper metal plate 500 may include multiple metal layers (not shown). In some embodiments, upper metal plate 500 may include gold (Au), but the present disclosure is not limited to Au, and some embodiments include layers of different metals (e.g., titanium (Ti)/Au). Upper metal plate 500 may be formed using conventional depositing, etching, and/or photolithography processes. Deposition procedures can include atomic layer deposition (ALD), chemical vapor deposition (CVD), physical vapor deposition (PVD), or other processes.

Dielectric layer 502 may be formed of conventional dielectric insulating material, such as silicon oxides or metal nitrides (e.g., silicon nitride), for example. Dielectric layer 502 may be formed by ALD, CVD, PCD, or the like.

Lower metal surface 504 may include a Au layer or multiple layers of metal. For example, lower metal surface 504 may include titanium (Ti)/(Au). Lower metal surface 504 may be formed using a conventional depositing, etching, and/or photolithography process. Deposition procedures can include ALD, CVD, PVD, or other processes

Substrate bottom metal layer 512 is formed over the substrate second surface 510. Substrate bottom metal layer 512 can couple the MIM capacitor device 302 to ground. Substrate bottom metal later 512 can include various conductive materials, such as Ti, copper (Cu), etc. Substrate bottom metal layer 512 may include multiple conductive layers.

One or more vias 306 may be formed in substrate 508. As shown in FIG. 5, substrate 508 includes substrate first surface 508 and substrate second surface 510. Lower metal surface 504 may serve as a lower capacitor plate. Lower metal surface 504 is over one or more vias 306 and an adjacent portion of substrate first surface 506. Lower metal surface 504 is electrically coupled to substrate bottom metal layer 512 with one or more vias 306, and thereby can provide a ground connection to substrate bottom metal layer 514 (e.g., a low inductance ground connection).

While some embodiments herein are described with reference to a MIM capacitor device that includes one or more vias, the present disclosure is not so limited, and includes MIM capacitor devices that do not include one or more vias.

Referring to FIGS. 3, 4, and 5, in the illustrated embodiments the upper metal plate 500 of the MIM capacitor device 302 is configured to serve as a wire bonding surface to attach with at least one wire bond 304 to a component or a circuit on a separate surface 102 in package/submount 300. The separate surface of circuit/component 102 can include one of a substrate, a die, a submount, and a carrier.

In some embodiments, the component or the circuit 102 includes a GaN based HEMT.

The component or the circuit 102 can include an IPD that includes one or more passive electronic components. The IPD can include SiC components. In an example embodiment, the component/circuit 102 includes an IPD with SiC components, and the MIM capacitor includes a shunt capacitor.

In other embodiments, the component or circuit 102 includes a MMIC. The MMIC can include a Group III nitride-based material or SiC. In an example embodiment, the component/circuit 102 includes a MMIC, and the MIM capacitor includes a series blocking capacitor or a shunt direct current (DC) bypass capacitor.

The device of various embodiments can include a MIM capacitor having a capacitance in a range of about 1 to 1000 pF. In some embodiments, the device is an RF device (e.g., an RF transistor package) and the MIM capacitor has a capacitance in a range of about 1-150 pF. In other embodiments, the MIM capacitor comprises a base-band or a decoupling capacitor and the MIM capacitor has a capacitance in a range of about 50-1,500 pF (e.g., for high frequency MIMICs, an initial decoupling capacitor may have a lower value than for a discrete, low frequency device).

Some embodiments are directed to a RF transistor package. The RF transistor package includes a submount, and a transistor die mounted on the submount. The transistor die includes a top surface and a bottom surface. The bottom surface is mounted to the submount. The RF transistor package further includes a MIM capacitor mounted to the submount. The MIM capacitor includes a substrate, a lower metal surface attached to a first surface of the substrate, and an upper metal plate configured to serve as a wire bonding surface. The RF transistor package further includes a wire bond including a first end connected to the wire bonding surface of the MIM capacitor and a second end connected to the top surface of the transistor die in the RF transistor package. The substrate of the MIM capacitor can include SiC.

In an example embodiment of FIGS. 3-5, the RF transistor package includes a submount 300, and a transistor die 102 mounted on the submount 300. The transistor die 102 can include one or a plurality of GaN based HEMTS. The transistor die 102 includes a top surface and a bottom surface. The bottom surface of the transistor die 102 is mounted to the submount 300. The RF transistor package 300 further includes a MIM capacitor 302 mounted to the submount 300. The MIM capacitor 302 includes a substrate 508, a lower metal surface 504 attached to a first surface of the substrate 5-6, and an upper metal plate 500 configured to serve as a wire bonding surface. The RF transistor package 300 further includes a wire bond 304 including a first end connected to the wire bonding surface of the MIM capacitor 302 and a second end connected to the top surface of the transistor die 102 in the RF transistor package 300.

The MIM capacitor may include a shunt capacitor. In some embodiments, the MIM capacitor includes a series blocking capacitor or a shunt DC bypass capacitor.

The MIM capacitor of the RF transistor package can have a capacitance in a range of about 1 to 1000 pF (e.g., in a range of about 1-150 pF).

In yet other embodiments, a device includes a MIM capacitor including (i) a substrate including a first surface and a second surface, (ii) an upper metal plate configured for wire bonding, (iii) a lower metal surface attached to the first surface of the substrate, (iv) a dielectric material disposed between the upper metal plate and the lower metal surface, and (v) at least one via disposed through the substrate. The substrate can include SiC.

The at least one via disposed through the substrate is surrounded by material of the substrate. The upper metal plate configured for wire bonding is disposed on the via and the surrounding material of the substrate. The upper metal plate configured for wire bonding is configured for at least one wire bond attachment to the upper metal plate disposed on a portion of the surrounding material of the substrate.

In some embodiments, the upper metal plate configured for wire bonding is configured to attach with at least one wire bond to a component or a circuit on a separate surface in a package. The separate surface can include one of a substrate, a die, a submount, and a carrier.

The component or circuit can include an IPD that includes one or more passive electronic components. The IPD can include SiC components. In some embodiments, the component or the circuit includes an IPD, and the MIM capacitor includes a shunt capacitor.

The component or circuit can include a MMIC. The MMIC can include a Group III nitride-based material on SiC. In some embodiments, the component or the circuit includes a MMIC, and the MIM capacitor includes a series blocking capacitor or a shunt DC bypass capacitor.

The device can include a MIM capacitor having a capacitance in a range of about 1 to 1000 pF. For example, the device can be a RF device (e.g., an RF transistor package) and the MIM capacitor may have a capacitance in a range of about 1-150 pF. In other embodiments, the MIM capacitor comprises a base-band or a decoupling capacitor and the MIM capacitor has a capacitance in a range of about 50-1,500 pF.

In an example embodiment according to FIGS. 3-5, the device 302 includes a MIM capacitor including (i) a substrate 508 including a first surface 506 and a second surface 512, (ii) an upper metal plate 500 configured for wire bonding, (iii) a lower metal surface 514 attached to the first surface of the substrate 508, (iv) a dielectric material 502 disposed between the upper metal plate 500 and the lower metal surface 512, and (v) at least one via 306 disposed through the substrate 508.

In the example embodiment, the at least one via 306 disposed through the substrate 508 is surrounded by material of the substrate 508. The upper metal plate 500 configured for wire bonding is disposed on the via 306 and the surrounding material of the substrate 508. The upper metal plate 500 configured for wire bonding is configured for at least one wire bond 304 attachment to the upper metal plate 500 disposed on a portion of the surrounding material of the substrate 508. The upper metal plate 500 configured for wire bonding is configured to attach with at least one wire bond 304 to a component or a circuit 102 on a separate surface in the package 300. The separate surface can include one of a substrate, a die, a submount, and a carrier of circuit/component 102.

FIGS. 3-5 are exaggerated views for the purpose of illustration only and are not intended to represent the true scale and structure of actual devices, components, circuits and/or packages.

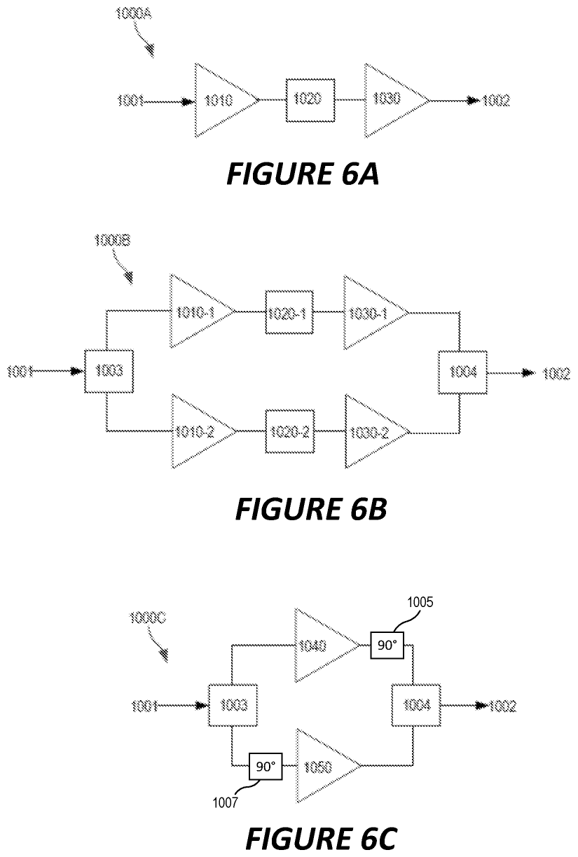

Referring to FIG. 6A, an RF transistor amplifier 1000A is schematically illustrated that includes a pre-amplifier 1010 and a main amplifier 1030 that are electrically connected in series. As shown in FIG. 6A, RF transistor amplifier 1000A includes an RF input 1001, the pre-amplifier 1010, an inter-stage impedance matching network 1020, the main amplifier 1030, and an RF output 1002. The inter-stage impedance matching network 1020 may include, for example, inductors and/or capacitors arranged in any appropriate configuration in order to form a circuit that improves the impedance match between the output of pre-amplifier 1010 and the input of main amplifier 1030. While not shown in FIG. 6A, RF transistor amplifier 1000A may further include a wire bond connection between pre-amplifier 1010 and MIM capacitor device 302, and/or a wire bond connection between the main amplifier 1030 and a MIM capacitor 302. The RF transistor amplifiers according to embodiments may be used to implement either or both of the pre-amplifier 1010 and the main amplifier 1030.

Referring to FIG. 6B, an RF transistor amplifier 1000B is schematically illustrated that includes an RF input 1001, a pair of pre-amplifiers 1010-1, 1010-2, a pair of inter-stage impedance matching networks 1020-1, 1020-2, a pair of main amplifiers 1030-1, 1030-2, and an RF output 1002. A splitter 1003 and a combiner 1004 are also provided. Pre-amplifier 1010-1 and main amplifier 1030-1 (which are electrically connected in series) are arranged electrically in parallel with pre-amplifier 1010-2 and main amplifier 1030-2 (which are electrically connected in series). As with the RF transistor amplifier 1000A of FIG. 6A, RF transistor amplifier 1000B may further include a direct wire bond attachment to a MIM capacitor device 302 (not shown).

As shown in FIG. 6C, the RF transistor amplifiers according to some embodiments may also be used to implement Doherty amplifiers. As is known in the art, a Doherty amplifier circuit includes first and second (or more) power-combined amplifiers. The first amplifier is referred to as the “main” or “carrier” amplifier and the second amplifier is referred to as the “peaking” amplifier. The two amplifiers may be biased differently. For example, the main amplifier may comprise a Class AB or a Class B amplifier while the peaking amplifier may be a Class C amplifier in one common Doherty amplifier implementation. The Doherty amplifier may operate more efficiently than balanced amplifiers when operating at power levels that are backed off from saturation. An RF signal input to a Doherty amplifier is split (e.g., using a quadrature coupler), and the outputs of the two amplifiers are combined. The main amplifier is configured to turn on first (i.e., at lower input power levels) and hence only the main amplifier will operate at lower power levels. As the input power level is increased towards saturation, the peaking amplifier turns on and the input RF signal is split between the main and peaking amplifiers.

As shown in FIG. 6C, the Doherty RF transistor amplifier 1000C includes an RF input 1001, an input splitter 1003, a main amplifier 1040, a peaking amplifier 1050, an output combiner 1004 and an RF output 1002. The Doherty RF transistor amplifier 1000C includes a 90° transformer 1007 at the input of the peaking amplifier 1050 and a 90° transformer 1005 at the input of the main amplifier 1040, and may optionally include input matching networks and/or an output matching networks (not shown). The inter-stage impedance matching network 1020, splitter 1003, combiner 1004, the main amplifier 1040, and/or the peaking amplifier 1050 may include a direct wire bond attachment to a MIM capacitor device 302 (not shown) according to embodiments described herein.

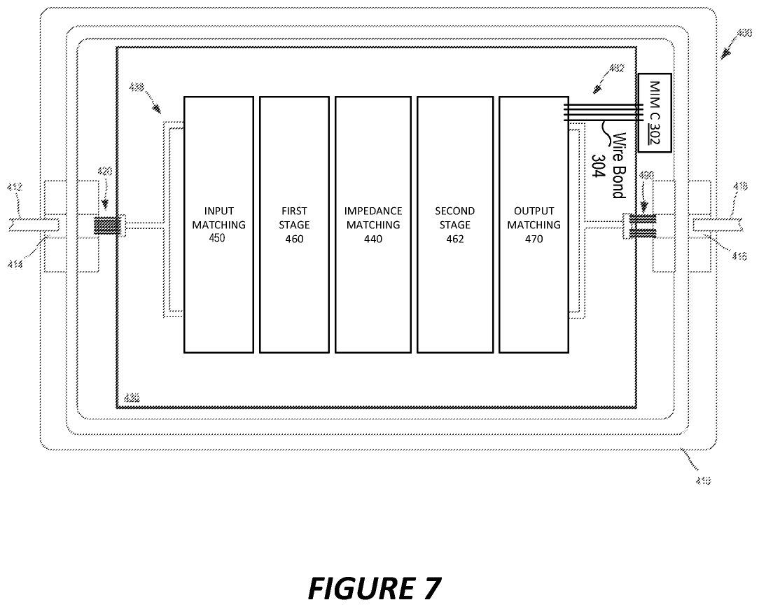

FIG. 7 is a schematic illustration of a plan view of a MMIC amplifier in which a HEMT transistor connected to a MIM capacitor device according to embodiments may be used. As shown in FIG. 5, the MMIC RF transistor amplifier 400 includes an integrated circuit chip 430 that is contained within a package 410. The package 410 may comprise a protective housing that surrounds and protects the integrated circuit chip 430. The package 410 may be formed of, for example, a ceramic material.

The package 410 includes an input lead 412 and an output lead 418. The input lead 412 may be mounted to an input lead pad 414 by, for example, soldering. One or more input bond wires 420 may electrically connect the input lead pad 414 to an input bond pad on the integrated circuit chip 430. The integrated circuit chip 430 includes an input feed network 438, an input impedance matching network 450, a first RF transistor amplifier stage 460, an intermediate impedance matching network 440, a second RF transistor amplifier stage 462, an output impedance matching stage 470, and an output feed network 482. The package 410 also includes MIM capacitor 302. A direct wire bond attachment to MIM capacitor device 302 is shown with a first end of wire bonds 304 directly attached to MIM capacitor 302 according to embodiments described herein. A second end of wire bonds 304 are attached to output impedance matching network 470.

The package 410 further includes an output lead 418 that is connected to an output lead pad 416 by, for example, soldering. One or more output bond wires 490 may electrically connect the output lead pad 416 to an output bond pad on the integrated circuit chip 430. The first RF transistor amplifier stage 460 and/or the second RF transistor amplifier stage 462 may be implemented using any of the RF transistor amplifiers according to embodiments of the present disclosure.

The RF transistor amplifiers according to embodiments of the present inventive concepts may be designed to operate in a wide variety of different frequency bands.

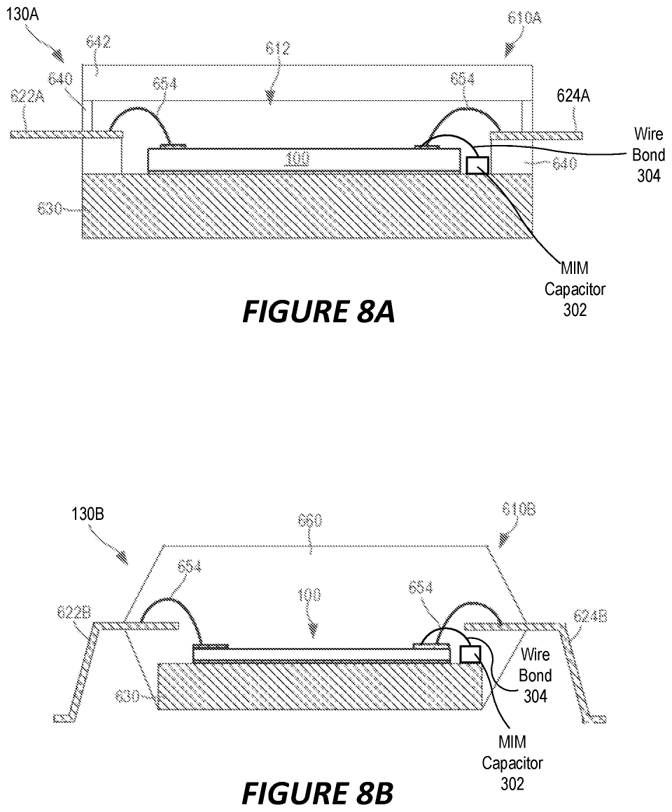

FIG. 8A is a schematic side view of a packaged MMIC RF transistor amplifier 130A. As shown in FIG. 8A, packaged RF transistor amplifier 130A includes a MMIC die 100 packaged in an open cavity package 610A. The package 130A includes metal gate leads 622A, metal drain leads 624A, a metal submount 630, sidewalls 640 and a lid 642.

The submount 630 may include materials configured to assist with the thermal management of the package 130A. For example, the submount 630 may include copper and/or molybdenum. In some embodiments, the submount 630 may be composed of multiple layers and/or contain vias/interconnects. In an example embodiment, the submount 630 may be a multilayer copper/molybdenum/copper metal flange that comprises a core molybdenum layer with copper cladding layers on either major surface thereof. In some embodiments, the submount 630 may include a metal heat sink that is part of a lead frame or metal slug. The sidewalls 640 and/or lid 642 may be formed of or include an insulating material in some embodiments. For example, the sidewalls 640 and/or lid 642 may be formed of or include ceramic materials.

In some embodiments, the sidewalls 640 and/or lid 642 may be formed of, for example, Al₂O₃. The lid 642 may be glued to the sidewalls 640 using an epoxy glue. The sidewalls 640 may be attached to the submount 630 via, for example, braising. The gate lead 622A and the drain lead 624A may be configured to extend through the sidewalls 640, though embodiments of the present inventive concepts are not limited thereto.

The MMIC die 100 is mounted on the upper surface of the metal submount 630 in an air-filled cavity 612 defined by the metal submount 630, the ceramic sidewalls 640 and the ceramic lid 642. The gate and drain terminals of MMIC die 100 may be on the top side of the structure, while the source terminal is on the bottom side of the structure.

The gate lead 622A may be connected to the gate terminal of MMIC die 100 by one or more bond wires 654. Similarly, the drain lead 624A may be connected to the drain terminal of MMIC die 100 by one or more bond wires 654. The source terminal may be mounted on the metal submount 630 using, for example, a conductive die attach material (not shown). The metal submount 630 may provide the electrical connection to the source terminal 126 and may also serve as a heat dissipation structure that dissipates heat that is generated in the RF transistor amplifier die 100.

The heat is primarily generated in the upper portion of the MMIC die 100 where relatively high current densities are generated in, for example, the channel regions of the unit cell transistors. This heat may be transferred though the source vias 146 and the semiconductor layer structure of the device to the source terminal and then to the metal submount 630.

A MIM capacitor 302 is mounted on the submount 630 proximate the MMIC die 100. A first end of a wire bond 304 is directly attached to the MIM capacitor 302, and a second end of the wire bond is attached to the drain of the MMIC die 100.

FIG. 8B is a schematic side view of another packaged MMIC RF transistor amplifier 130B. The MMIC transistor amplifier 130B differs from the MMIC RF transistor amplifier 130A in that it includes a different package 610B. The packaged MMIC RF transistor amplifier 130B includes a metal submount 630, as well as metal gate and drain leads 622B, 624B. The packaged MMIC RF transistor amplifier 130B also includes a plastic overmold 660 that at least partially surrounds the RF transistor amplifier die 100, the leads 622B, 624B, and the metal submount 630.

A MIM capacitor 302 is mounted on the submount 630 proximate the MMIC die 100. A first end of a wire bond 304 is directly attached to the MIM capacitor 302, and a second end of the wire bond is attached to the drain of the MMIC die 100.

While embodiments discussed above are explained in the non-limiting context of a packaged MMIC RF transistor amplifier that includes a MIM capacitor mounted on a submount proximate a MMIC die, the disclosure is not so limited. Instead, other packages may be used, including without limitation, an overmolded package that includes a discrete GaN transistor die and a MIM capacitor that is directly attached to the GaN transistor die.

Devices as described herein may be used in amplifiers that operate in a wide variety of different frequency bands. In some embodiments, packaged RF transistor amplifiers incorporating transistor devices and MIM capacitors as described herein may be configured to operate at frequencies greater than 1 GHz. In other embodiments, the RF transistor amplifiers may be configured to operate at frequencies greater than 2.5 GHz. In still other embodiments, the RF transistor amplifiers may be configured to operate at frequencies greater than 3.1 GHz. In yet additional embodiments, the RF transistor amplifiers may be configured to operate at frequencies greater than 5 GHz. In some embodiments, the RF transistor amplifiers may be configured to operate in at least one of the 2.5-2.7 GHz, 3.4-4.2 GHz, 5.1-5.8 GHz, 12-18 GHz, 18-27 GHz, 27-40 GHz or 40-75 GHz frequency bands or sub-portions thereof.

Although embodiments of the inventive concepts have been discussed above with respect to HEMT devices, MMICs, and IPDS, it will be understood that the inventive concepts described herein may be applied to other types of semiconductor devices, such as MOSFETs, DMOS transistors, GaAs CMOS, and/or laterally diffused MOS (LDMOS) transistors.

Packaged RF transistor amplifiers incorporating transistor devices and MIM capacitors described herein can be used in standalone RF transistor amplifiers and/or in multiple RF transistor amplifiers. Examples of how the RF transistor amplifiers according to some embodiments may be used in applications that include multiple amplifiers discussed with reference to FIGS. 6A-6C.

The RF transistor amplifiers according to embodiments may be formed as discrete devices, or may be formed as part of a MMIC or an IPD.

A transistor device according to some embodiments may be utilized in power semiconductor devices and/or applications. In some embodiments, the power semiconductor devices may be utilized for a power module that may include structure optimized for state-of-the-art wide band gap power semiconductor devices such as GaN or other Group III-nitride materials, SiC, and the like, which are capable of carrying high amounts of currents and voltages and switching at increasingly faster speeds in comparison with established technologies. The power devices may include Wide Band Gap (WBG) semiconductors, including GaN, SiC, and the like, and offer numerous advantages over conventional Silicon (Si) as a material for the power devices. Nevertheless, various aspects of the disclosure may utilize Si type power devices and achieve a number of the benefits described herein.

A transistor device according to some embodiments may be utilized in radio frequency (RF) applications. In particular, a transistor device according to some embodiments may be utilized in wireless base stations that connect to a wireless device. In further aspects, the transistor device may be utilized in in wireless communication devices.

Although embodiments of the inventive concepts have been described in considerable detail with reference to certain configurations thereof, other versions are possible. The MIM capacitor device can also have many different shapes. Accordingly, the spirit and scope of the invention should not be limited to the specific embodiments described above.

What is claimed is:

1. A device comprising:
a metal-insulator-metal (MIM) capacitor comprising a substrate, an upper metal plate, and a lower metal surface attached to a first surface of the substrate,
wherein the upper metal plate of the MIM capacitor is configured to serve as a wire bonding surface.

2. The device of claim 1, wherein the upper metal plate of the MIM capacitor configured to serve as a wire bonding surface is configured to attach with at least one wire bond to a component or a circuit on a separate surface in a package.

3. The device of claim 2, wherein the separate surface in the package comprises one of a substrate, a die, a submount, and a carrier.

4. The device of claim 2, wherein the component or the circuit comprises a gallium nitride (GaN) based high-electron-mobility transistor (HEMT).

5. The device of claim 2, wherein the component or the circuit comprises an integrated passive device (IPD) comprising one or more passive electronic components.

6. The device of claim 5, wherein the IPD comprises silicon carbide (SiC) components.

7. The device of claim 6, wherein the MIM capacitor comprises a shunt capacitor.

8. The device of claim 2, wherein the component or the circuit comprises a monolithic microwave integrated circuit (MMIC).

9. The device of claim 2, wherein the MMIC comprises a Group III nitride-based material on silicon carbide (SiC).

10. The device of claim 9, wherein the MIM capacitor comprises a series blocking capacitor or a shunt direct current (DC) bypass capacitor.

11. The device of claim 1, wherein the substrate comprises silicon carbide (SiC).

12. The device of claim 1, wherein the MIM capacitor has a capacitance in a range of about 1 to 1000 pF.

13. The device of claim 1, wherein the device comprises a gallium nitride (GaN) based high-electron-mobility transistor (HEMT).

14. The device of claim 1, wherein the device is configured to operate at frequencies greater than 1 GHz.

15. The device of claim 1, wherein the device is configured to operate at frequencies greater than 2.5 GHz.

16. The device of claim 1, wherein the device is configured to operate at frequencies greater than 3.1 GHz.

17. The device of claim 1, wherein the device is configured to operate at frequencies greater than 5 GHz.

18. An RF transistor package, comprising:
a submount;
a transistor die mounted on the submount, the transistor die comprising a top surface and a bottom surface, wherein the bottom surface is mounted to the submount;
a metal-insulator-metal (MIM) capacitor mounted to the submount, wherein the MIM capacitor comprises a substrate, a lower metal surface attached to a first surface of the substrate, and an upper metal plate configured to serve as a wire bonding surface; and
a wire bond comprising a first end connected to the wire bonding surface of the MIM capacitor and a second end connected to the top surface of the transistor die in the RF transistor package.

19. The RF transistor package of claim 18, wherein the transistor die comprises one or a plurality of gallium nitride (GaN) based high-electron-mobility transistors (HEMTs).

20. The RF transistor package of claim 18, wherein the MIM capacitor comprises a shunt capacitor.

21. The RF transistor package of claim 18, wherein the MIM capacitor comprises a series blocking capacitor or a shunt direct current (DC) bypass capacitor.

22. The RF transistor package of claim 18, wherein the substrate of the MIM capacitor comprises silicon carbide (SiC).

23. The RF transistor package of claim 18, wherein the MIM capacitor has a capacitance in a range of about 1 to 1000 pF.

24. The RF transistor package of claim 18, wherein the substrate of the MIM capacitor comprises silicon carbide (SiC).

25. The RF transistor package of claim 18, wherein the RF transistor package is configured to operate at frequencies greater than 1 GHz.

26. The RF transistor package of claim 18, wherein the RF transistor package is configured to operate at frequencies greater than 2.5 GHz.

27. The RF transistor package of claim 18, wherein the RF transistor package is configured to operate at frequencies greater than 3.1 GHz.

28. The RF transistor package of claim 18, wherein the RF transistor package is configured to operate at frequencies greater than 5 GHz.

29. A device comprising:
a metal-insulator-metal (MIM) capacitor comprising (i) a substrate comprising a first surface and a second surface, (ii) an upper metal plate configured for wire bonding, (iii) a lower metal surface attached to the first surface of the substrate, (iv) a dielectric material disposed between the upper metal plate and the lower metal surface, and (v) at least one via disposed through the substrate.

30. The device of claim 29, wherein the at least one via disposed through the substrate is surrounded by material of the substrate, the upper metal plate configured for wire bonding is disposed on the via and the surrounding material of the substrate, and the upper metal plate configured for wire bonding is configured for at least one wire bond attachment to the upper metal plate disposed on a portion of the surrounding material of the substrate.

31. The device of claim 29, wherein the upper metal plate configured for wire bonding is configured to attach with at least one wire bond to a component or a circuit on a separate surface in a package.

32. The device of claim 31, wherein the separate surface comprises one of a substrate, a die, a submount, and a carrier.

33. The device of claim 31, wherein the component or the circuit comprises an integrated passive device (IPD) comprising one or more passive electronic components.

34. The device of claim 33, wherein the IPD comprises silicon carbide (SiC) components.

35. The device of claim 33, wherein the MIM capacitor comprises a shunt capacitor.

36. The device of claim 31, wherein the component or the circuit comprises a monolithic microwave integrated circuit (MMIC).

37. The device of claim 36, wherein the MMIC comprises a Group III nitride-based material on silicon carbide (SiC).

38. The device of claim 36, wherein the MIM capacitor comprises a series blocking capacitor or a shunt direct current (DC) bypass capacitor.

39. The device of claim 29, wherein the substrate comprises silicon carbide (SiC).

40. The device of claim 29, wherein the MIM capacitor has a capacitance in a range of about 1 to 1000 pF.

41. The device of claim 29, wherein the device comprises a gallium nitride (GaN) based high-electron-mobility transistor (HEMT).

42. The device of claim 29, wherein the device is configured to operate at frequencies greater than 1 GHz.

43. The device of claim 29, wherein the device is configured to operate at frequencies greater than 2.5 GHz.

44. The device of claim 29, wherein the device is configured to operate at frequencies greater than 3.1 GHz.

45. The device of claim 29, wherein the device is configured to operate at frequencies greater than 5 GHz.
